(19) United States
(12) Patent Application Publication
(10) Pub. No.: US 2025/0301717 A1
(43) Pub. Date: Sep. 25, 2025

(54) INTEGRATED COOLING STRUCTURE FOR SEMICONDUCTOR QUBIT QUANTUM DEVICE

(71) Applicant: COMMISSARIAT A L'ENERGIE ATOMIQUE ET AUX ENERGIES ALTERNATIVES, Paris (FR)

(72) Inventors: Charles BON MARDION, Grenoble Cedex 09 (FR); Candice THOMAS, Grenoble Cedex 09 (FR); Benoit BERTRAND, Grenoble Cedex 09 (FR); Baptiste JADOT, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/086,712

(22) Filed: Mar. 21, 2025

(30) Foreign Application Priority Data
Mar. 22, 2024 (FR) FR2402908

(51) Int. Cl. H10D 48/00; H01L 23/34; H10N 60/80

(52) U.S. Cl. CPC H10D 48/3835; H01L 23/34; H10N 60/805

(57) ABSTRACT

A structure for cooling a component of a quantum device by circulating a given current between a first contact element with the component and a second contact element with the component, the first contact element comprising at least one given superconducting metal material, in particular at a given temperature less than 2K, and being in contact by a first end with a first semiconductor portion of said component so as to form with the first semiconductor portion at least one cooling tunnel junction.

### TECHNICAL FIELD AND PRIOR ART

The present application relates to the field of quantum electronic devices, in particular those having qubits formed in a semiconductor region, and relates to an improved integrated structure for cooling such a type of device, and to a manufacturing method. Quantum devices rely on qubits (sometimes also written as “Qbits”) or quantum bits as information vectors, i.e. information bits based on a given quantum state among at least two measurable levels. The qubits can be formed in a semiconductor material within electrostatically controlled nanometric-sized confinement structures. These confinement structures are typically known as “quantum dots”. A quantum dot acts as a potential well confining one or more elementary charges (electrons or holes) in a semiconductor region. A particular type of semiconductor qubit is the spin qubit when the degree of spin freedom of electrons or holes is used to encode quantum information. To measure the state of a spin qubit, it is known in particular to perform a spin/charge conversion which makes it possible to convert the spin state of the charged particles into a charge state of the quantum dots containing said particles. It is then necessary to measure this charge state in order to derive the spin state of the charged particles before conversion. For this, a means for measuring the charge state is generally disposed near each quantum dot.

A qubit can in particular be read using another quantum dot known as a “reading island” or “detection island” coupled with that of the qubit to be read. These two elements form two potential wells separated by a potential barrier. Such devices generally operate at a very low temperature, i.e. typically of the order of one Kelvin or a few hundred milli-Kelvin, to prevent thermal noise from destroying quantum coherence. Compared to the field of superconductor qubits where the temperature range is limited to a few tens of milli-Kelvin, the operation of spin qubits has already been demonstrated at 1.5 K, offering other possibilities for their cooling. The qubits are cooled by placing the device in a cooling system or cryostat capable of reaching temperatures of the order of ten milli-Kelvin.

However, it is also sought to improve thermal management within the device itself, for example between components intended to store quantum information, for which the operating temperature is critical, but typically having a low thermal dissipation, and associated control components in the form for example of a reading circuit produced in CMOS technology, for which the operating temperature is less critical, but typically having a high thermal dissipation.

For co-integration of these elements, an operating temperature of 1 K can be preferred in order to increase the cooling power available from the cryostat for thermalization of the system.

Document FR3º114º443 describes a solution consisting in providing, in a zone, conductive routing tracks fulfilling a thermal and electrical conductor function, and superconducting routing tracks fulfilling an electrical conductor and thermal insulator function. This makes it possible to improve thermalization on a system scale while ensuring good thermal insulation between quantum or qubit components and control components.

In another field, that of superconductor qubits (encoding quantum information on anharmonic resonators made from Josephson junctions), documents US2022/0138609, WO2023/156701A1 and U.S. Pat. No. 11,302,857B2 propose a cooling method on a superconductor qubit scale by means of an offset cooling tunnel junction away from the qubits

The problem arises of improving the thermal management of a semiconductor qubit quantum device, in particular on a qubit scale, while limiting the size required for this management.

### DESCRIPTION OF THE INVENTION

Hence, an aim of the present invention is that of providing a cooling structure for a semiconductor qubit quantum device which is integrated inside or as close as possible to the quantum or control components to be cooled.

For this purpose, according to an embodiment, the present invention provides a quantum electronic device, in particular with spin qubits, comprising a substrate and a component disposed on the substrate, the component comprising at least one so-called “channel” region formed in at least one semiconductor layer and including one or more islands, each island being controlled via an electrostatic control gate and forming a quantum dot or a detection island for reading the quantum state of a quantum dot, the device further comprising: a structure provided for cooling the component by circulating a given current between a first contact element with the component and a second contact element with the component, the first contact element comprising at least one given superconducting metal material, the first contact element being in contact by a first end with a first semiconductor portion of the component so as to form with the first semiconductor portion at least one tunnel junction.

This tunnel junction, also known as a “cooling” junction, is in particular of the NS (“Normal” “Superconductor”) or NIS (“Normal” “Insulator” “Superconductor”) type.

The component is thus cooled as close as possible to the semiconductor layer(s) wherein the qubits are provided, while not impacting the size, which is essential for quantum device scalability. This integrated local cooling solution particularly makes it possible to improve the stability of quantum operations, protecting from heat dissipated by nearby control components integrated monolithically or by 3D integration techniques.

Besides the compact aspect of such a cooling structure and the possibility of cooling as close as possible to the qubits, such a structure has the advantage of being capable of being integrated without requiring a number of additional steps and/or substantial adaptations of the manufacturing method. The choice of materials used makes it possible to obtain such a tunnel junction in the quantum component and/or the control component.

According to an advantageous embodiment, the given superconducting metal material can be a material having a critical temperature Tc greater than 2 K, advantageously greater than 4 K, such as TiN.

Advantageously, the first contact element can be, from the first end to a second end, formed from the given superconducting metal material.

Alternatively, the first contact element includes, at the first end, a stack of a dielectric zone in contact with the first semiconductor portion and a section based on the given superconducting metal material.

Advantageously, this dielectric zone can be an oxidized zone of the semiconductor material of the first semiconductor portion.

According to a particular configuration, the first contact element can include, at the first end, a stack of the given superconducting material and of a second superconducting material having a higher gap than the given superconducting material, the second higher-gap superconducting material being in contact with the first semiconductor portion.

Such a configuration makes it possible to prevent hot electrons from returning to the semiconductor portion and hence makes it possible to increase cooling performance.

According to an embodiment wherein the channel region extends in a first parallel or substantially parallel direction to a main plane of the substrate and wherein the first element extends in an orthogonal or substantially orthogonal direction to the first direction, the first contact element can be connected by a second end to a metal track of superconducting metal material parallel or substantially parallel to the main plane of the substrate.

Advantageously, the first contact element can be formed from a set of contact pads connected in parallel to the metal track.

Placing several contacts in parallel can reduce the resistance of the insulating barrier and increase the cooling power.

According to an advantageous implementation, the second contact element can comprise at least one superconducting metal material and be in contact with a second semiconductor portion of the component so as to form with the second semiconductor portion at least a second NS or NIS tunnel junction. A configuration wherein the NS or NIS junction is connected in series with the second junction and where a cooling current is circulated through the two junctions can thus advantageously be provided. This configuration is especially efficient as symmetrization of the junctions is also implemented with respect to the zone N. In other words, identical superconducting zones “S” and, where applicable, insulating zones “I” are preferably provided between the junction and the second junction.

According to an implementation option, the second contact element is in contact with a second semiconductor portion of the component and the channel region extends between a so-called “source” semiconductor region and a second so-called “drain” semiconductor region, the first semiconductor portion and the second semiconductor portion each being portions of the source region or the drain region.

Advantageously, the structure for cooling the component further comprises a third contact element in contact with a third semiconductor portion of the component and a fourth contact element in contact with a fourth semiconductor portion of the component, the third contact element forming a tunnel junction, in particular of the NIS or NS type with the third semiconductor portion of the component, the third semiconductor portion and the fourth semiconductor portion each being portions of an electrostatic control gate of the component.

The second contact element can be in contact with a second semiconductor portion of the component whereas the first semiconductor portion and the second semiconductor portion are each portions of an electrostatic control gate.

According to a possible implementation, the second contact element is in contact with a second semiconductor portion of the component and the “channel” region includes one or more detection islands for reading the quantum state of one or more quantum dots of another part of the component or of another component and wherein the channel region extends between a first so-called “source” semiconductor region and a second so-called “drain” semiconductor region, the first portion and the second portion being: respectively a portion of the source region and a portion of the drain region.

According to an embodiment option, in order to facilitate cooling, at least one cavity arranged facing the component can be provided in the substrate.

Advantageously, each island of the component can form a quantum dot, the device further comprising: another component for reading the quantum state of the component, the device further comprising a structure provided for cooling the other component by circulating a given current between a contact element with this other component and another contact element with this other component, the contact elements forming at least one tunnel junction, in particular of the NIS or NS type, with a semiconductor portion of the other component.

The component and the other component can advantageously be connected by a metal interconnect line of a metal interconnect layer arranged in at least one insulating layer. According to a particular configuration, the metal interconnect line can be surrounded by a cavity forming an empty space around the metal interconnect line and surrounded by the insulating layer. This also contributes to better cooling.

According to another aspect, the present application relates to a method for manufacturing a device as defined hereinabove.

An embodiment in particular provides a method for manufacturing a device as defined hereinabove and comprising steps of:
providing the substrate and the component formed on the substrate,
in at least one insulating layer covering the component, producing at least a first hole and at least a second hole respectively revealing the first semiconductor portion and the second semiconductor portion of the component,
forming the first contact element in the first hole and the second contact element in the second hole, by depositing at least the given superconducting metal material in the first hole and in the second hole.

### BRIEF DESCRIPTION OF THE DRAWINGS

The present invention will be better understood on the basis of the following description and the appended drawings wherein:

FIG. 1 illustrates an example of a structure for cooling a component of a quantum device, the component including one or more quantum dots formed in a semiconductor zone, the structure having contact elements between which a current is circulated.

FIG. 2 illustrates a first particular exemplary embodiment of the cooling tunnel junction, here of the NS type and using a Schottky barrier, formed between the contact element and the portion of the component to be cooled.

FIG. 3 illustrates a second particular exemplary embodiment of the cooling junction, here of the NIS type, the insulator being formed from a native oxide between the contact element and the portion of the component to be cooled.

FIG. 4 illustrates a third particular exemplary embodiment of the cooling junction, here of the NIS type, the insulator being formed by a deposition of dielectric material between the contact element and the portion of the component to be cooled.

FIG. 5 illustrates a fourth particular exemplary embodiment of the cooling junction, here of the NS type, the superconducting contact being formed from two superconducting materials deposited one after the other.

FIG. 6 illustrates an exemplary embodiment for which the structure dedicated to cooling has contact elements both on the source region and on the drain region of the component.

FIG. 7 illustrates an exemplary embodiment for which the structure dedicated to cooling has contact elements on at least one electrostatic control gate of the component.

FIG. 8 illustrates an exemplary embodiment for which the structure dedicated to cooling has contact elements both on at least one electrostatic control gate as well as on the source and drain regions of the component.

FIG. 9 illustrates an exemplary embodiment wherein the structure for cooling is configured to cool a channel region having detection islands dedicated to detecting the quantum state of quantum dots.

FIG. 10 illustrates another example wherein the structure for cooling is configured both to cool the channel region provided with one or more detection islands and one or more control gates of this or these islands.

FIG. 11 illustrates an exemplary embodiment where several contact elements of the cooling structure are connected to the same superconducting track.

FIGS. 12A, 12B, 12C, 12D illustrate an exemplary embodiment of a quantum device component having at least one semiconductor layer intended to accommodate one or more quantum dots.

FIGS. 12E, 12F, 12G illustrate an exemplary embodiment of contact elements for a structure provided to cool the component.

FIG. 13 illustrates an exemplary embodiment wherein contact elements of the structure for cooling are furthermore arranged on electrostatic control gates of the quantum dots.

FIG. 14 illustrates an exemplary embodiment of metal tracks for polarizing the contact elements of the structure.

FIG. 15 illustrates an exemplary embodiment wherein the cooling structure is arranged both on a first component intended to accommodate one or more quantum dots and on a second component provided to detect the quantum state of the first component.

FIGS. 16A, 16B illustrate different arrangement options of an array of quantum or qubit components with respect to the associated control components.

FIG. 17 illustrates an alternative embodiment wherein one or more cavities are formed in the dielectric and/or in the substrate in order to limit the heat transfer via these media and thus limit the temperature rise of a quantum device comprising quantum and control components.

FIG. 18 illustrates a fifth particular embodiment of the cooling junction, here of the NIS type, with a superconducting contact formed from two stacked superconducting materials, the superconducting contact being surrounded by a dielectric material casing.

FIG. 19 illustrates a sixth particular embodiment of the cooling junction, here of the NIS type, with a superconducting contact formed from two stacked superconducting materials disposed on the oxide.

FIG. 20 illustrates an arrangement with two cooling NIS (or NS) tunnel junctions in series.

FIG. 21 illustrates a junction arrangement with two superconductors of different gaps joined together.

Identical, similar or equivalent parts of the different figures described hereinafter bear the same numerical references so as to facilitate the transition from one figure to another.

Furthermore, in the description hereinafter, terms dependent on the orientation of the structure such as “above”, “below”, “rear”, “front”, “top”, “bottom”, apply on the assumption that the structure is oriented as illustrated in the figures.

The individual parts shown in the figures are not necessarily shown according to a uniform scale, to make the figures more readable.

### DETAILED DESCRIPTION OF PARTICULAR EMBODIMENTS

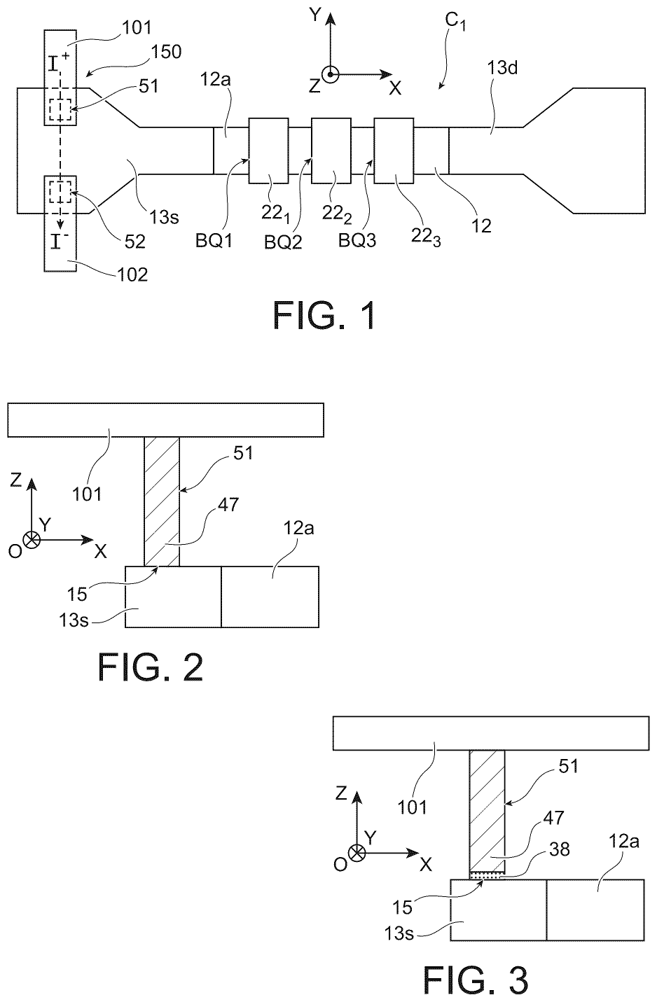

Reference is made firstly to FIG. 1 which gives a particular exemplary embodiment of a device having at least one quantum component C₁, in particular with spin qubits, according to a first embodiment and represented according to a top view.

The component C₁ including several quantum dots BQ1, BQ2, BQ3 each formed in an island of a so-called “channel” region 12a of the component extending into at least one semiconductor layer 12. This semiconductor layer 12 can be the surface layer of a substrate or a layer mounted or deposited on a substrate and formed from a semiconductor material or from several stacked semiconductor materials.

For example, the semiconductor layer 12 can be made of silicon or based on germanium. According to a particular embodiment, the semiconductor layer 12 is the surface layer of a semiconductor-on-insulator type substrate, in particular a silicon layer of an SOI (“Silicon On Insulator”) substrate.

The quantum dots BQ1, BQ2, BQ3 each ensure the confinement of at least one elementary charge (electron or hole). The spin of this charge, in particular of an electron, is here provided to encode the quantum information. The qubits associated respectively with the quantum dots BQ1, BQ2, BQ3 are spin qubits.

Electrostatic control gates 22₁, 22₂, 22₃ are provided facing each of the islands respectively forming the quantum dots BQ1, BQ2, BQ3 and are, in this particular exemplary embodiment, arranged above the semiconductor layer 12. The electrostatic control gates 22₁, 22₂, 22₃ can be formed from a metal material such as for example TIN, or semiconductor material such as for example polysilicon or a stack of metal and semiconductor material.

On either side of the region 12a, the component includes a semiconductor region 13s also known as “source” region forming a first reservoir of charges or dopants of the component C₁ and a semiconductor region 13d also known as “drain” region forming a second reservoir of charges or dopants of the component C₁. The semiconductor regions 13s, 13d, can be formed for example based on silicon and/or SiGe and/or Ge and are typically volume-doped.

The device here has the specificity of having an integrated cooling structure 150 for cooling the component C₁. This structure 150 includes a first contact element 51 and a second contact element 52, each in contact with a semiconductor region of the component C₁.

A cooling of the component C₁ is implemented by circulating a current (represented schematically in FIG. 1 with a dotted line) from the first element 51 to the second element 52. For this, it is provided that the first contact element 51, at least partially made of superconducting material, forms, with a semiconductor portion of the component with which this element is in contact, at least one NIS type (“Normal Insulator Superconductor”) cooling tunnel junction or at least one NS (“Normal Superconductor”) type cooling tunnel junction with a Schottky barrier. In the second configuration with a Schottky barrier, this actually consists of a particular case of an NIS junction where the Insulator “I” is replaced by a metal-superconductor contact to advantageously form the barrier of the junction.

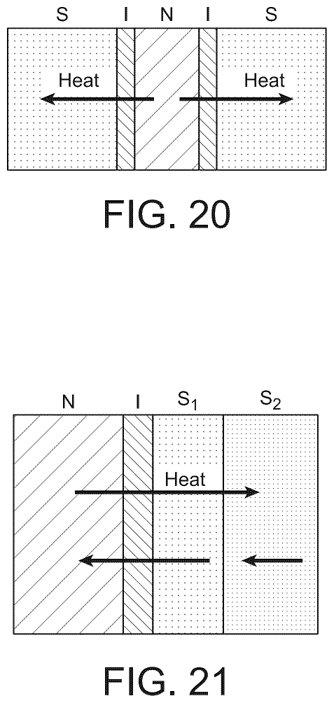

Several cooling tunnel junctions (NIS or NS) can be placed in series and/or in parallel. In order to increase the cooling power, as in FIG. 20, two NIS (or NS) cooling tunnel junctions placed in series can be provided to create an “SINIS” junction and thus double the cooling power. Preferably, a symmetry of the junctions placed in series is implemented, such that the thicknesses and materials of their insulating zones “I” are advantageously the same from one junction to the other whereas the superconductor thicknesses and materials of their zones “S” are also advantageously the same from one junction to the other.

For the superconducting material(s) of the element 51, a material having a superconductivity critical temperature Tc that is greater than 2 K is sought, advantageously greater than 4 K such as for example Niobium (Nb), Niobium Nitride (NbN), Titanium Nitride (TiN), Tantalum Nitride (TaN), Niobium-Titanium Nitride (NbTiN).

An NIS junction cooling principle is given in the document “Micrometer-scale refrigerators”, by Juha T Muhonen et al, 2012 Rep. Prog. Phys. 75 046501. The cooling structure according to the present invention has the advantage of being produced directly in or on the component to be cooled which allows a gain in terms of compactness and cooling efficiency.

To adequately polarize the junction and circulate a current capable of cooling the component, a voltage Vr_opt equal to

$$N \frac{( Δ - 0.66 {k}_{B} T )}{e}$$

is preferably applied between the contact element and the semiconductor portion, where N is typically equal to 1 or 2 and corresponds to the number of cooling tunnel junctions coupled electrically in series, A is the deviation in the superconductor state density e, is the elementary charge, KB is the Boltzmann constant, and T is the temperature.

The polarization voltage range depends on the material used and the temperature. For example, for TiN between 0.1 K and 4 K, the optimal polarization is typically within the range of 0.5 mV to 4 mV, typically of the order of 0.7 mV to 1 K.

At a temperature T<T_{C} where T_{C} is the critical temperature of the superconducting material, the optimum polarization voltage Vr_opt to obtain an optimum cooling power is for example of the order of 700 μV, for an NIS type cooling tunnel junction wherein S is TIN and operating at a temperature of 1 K. At 1 K, TiN is particularly adapted to make it possible to obtain maximum cooling. The use of TiN, which is commonly used in microelectronics, is also advantageous because it allows the manufacture of these integrated cooling junctions with industrial processes.

For a volume to be cooled of the order of 1.3*10⁻³ μm³ (corresponding for example to a semiconductor region with a length of 1 μm, a width of 60 nm and a thickness of 20 nm, encompassing the channel, the source and the drain, with an SINIS junction wherein S is TIN, assuming an insulating barrier resistance R_{T} of 1 kΩ, a cooling power is estimated at 1 K and at the voltage Vr_opt which can be for example of the order of 35 pW and in any case greater than that of electron heating by phonons and the Joule effect, the Joule effect being in this particular example of the order of 8 pW. Such conditions can be implemented for example in order to cool a component as described in the document “A new FDSOI spin qubit platform with 40 nm effective control pitch”, by T. Bédécarrats et al. 2021 IEEE International Electron Devices Meeting (IEDM).

A cooling current typically between 50 nA and

500 nA can be implemented. For example, when the cooling junction is of the NIS type, where the superconducting material S is TIN at 1 K, a current of 120 nA can be implemented.

The first contact element 51 and the second contact element 52 extend here in a direction creating a non-zero angle with a main plane of the substrate or the semiconductor layer 12, in particular an orthogonal direction to this main plane. “Main plane” of the substrate or the semiconductor layer 12 means a plane passing through the substrate or the semiconductor layer 12 and which is parallel to the plane [O;x;y] of the orthogonal reference frame [O;x;y;z].

In order to allow the application of polarization signals and/or potentials to them, the first contact element 51 and the second contact element 52 are here connected respectively to a first typically metal and preferably superconducting track 101, and a second typically metal and preferably superconducting track 102. For example, the tracks 101, 102 can be formed using one or more of the following superconducting materials: TIN, Nb, NbN, NbTiN, TaN. The metal tracks 101 and 102 can belong to a metal interconnect layer, for example of the first metal interconnect layer M₁, i.e. that provided just above the semiconductor layer and the contacts.

In order to allow the cooling current to establish between the contact elements 51 and 52, the metal tracks 101, 102 are here set to different potentials and in particular such that this difference in potentials corresponds to a voltage Vr_opt.

Various examples of configurations of the contact element 51 are given in FIGS. 2 to 5, and 18-19.

According to a first particular embodiment illustrated in FIG. 2, the first contact element 51 is made entirely of superconducting metal material 47, for example TiN, or TaN, or a Ti/TiN stack which can be deposited with a conformal deposition method such as CVD (“Chemical Vapor Deposition”), and is disposed directly in contact on a semiconductor portion 15 which can be doped, for example N-doped. This semiconductor portion 15 is here for example a portion of the source region 13s of the component.

Thus, a Schottky barrier is created between the element 51, and the semiconductor portion of the component with which this element 51 is in contact, thus forming an NS (“Normal Superconductor”) type cooling tunnel junction. The superconducting metal material 47 is then in direct contact with a doped semiconductor portion 15 which, preferably, is not siliconized or does not include a metal and semiconductor alloy zone as in a conventional transistor contact. The semiconductor portion 15 with which this element 51 is in contact is here preferably strongly doped, i.e. of the order of

10²⁰ cm⁻³ or higher.

A second exemplary embodiment of the contact element 51 is given in FIG. 3. The element 51 is this time formed from a main section made of superconducting metal material 47 connected to the track 101 and a dielectric zone 38, of a thickness which can be for example between 2 and 10 nm and which is arranged between one end of the section of superconducting metal material 47 and the semiconductor portion, preferably doped, of the component with which the element 51 is in contact. The doped semiconductor portion 15 for example of a source region 13s, the dielectric zone 38, and the section of superconducting metal material 47 here form an NIS (for “Normal Insulator Superconductor”) type cooling tunnel junction.

Advantageously, the dielectric zone 38 can be a semiconductor oxide zone, in particular formed by native or assisted oxidation of the semiconductor material of the doped semiconductor portion 15, for example a zone of SiO₂, when the doped semiconductor portion is made of silicon.

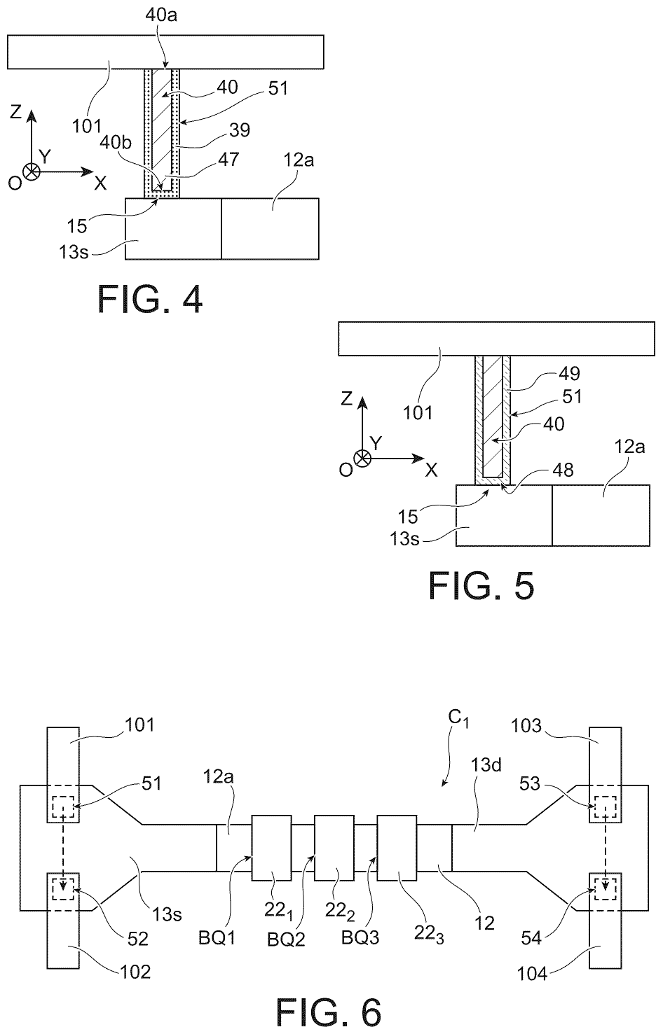

According to an alternative embodiment illustrated in FIG. 4, the contact element 51 is this time formed from a central part 40 made of superconducting metal material 47, for example in the form of a rod, of which one end 40a is in contact with the track 101. This central part 40 is surrounded by a dielectric material casing 39, which extends against the lateral edges of the central part 40 and here covers another end 40b opposite the end 40a. The dielectric casing 39 is itself in contact with the doped semiconductor portion (here the source region 13s). Thus, the doped semiconductor portion, the dielectric casing 39, and the central part 40 of superconducting metal material 47 form an NIS type cooling tunnel junction. The dielectric casing 39 can for example be based on SiO₂ deposited for example by PECVD (“Plasma-Enhanced CVD”) or by PEALD (“Plasma-Enhanced Atomic Layer Deposition”) or a high-k dielectric such as for example Al₂O₃ or HfO₂ deposited by PEALD.

According to another embodiment option, the contact element 51 can be formed from a superposition of several different superconducting metal materials with, preferably, the superconducting metal material having the highest superconducting gap placed in contact with the doped semiconductor portion.

Thus, in the particular exemplary embodiment illustrated in FIG. 5, the element 51 is this time formed from a central part 40, made of superconducting metal material 47 surrounded by a casing 48, made of a different superconducting metal material 49 from the superconducting metal material 47 and having in particular a greater gap than the superconducting metal material 47. The casing 48 is in contact with the doped semiconductor portion (here the source region 13s). The doped semiconductor portion, the casing 48 and the central part 40 here form an NS type cooling junction. For example, the casing 48 can be provided in TIN, and the central part 40 in Aluminum. Such a configuration of superconducting metal material 49 having the highest gap against the doped semiconductor portion makes it possible to prevent hot electrons from returning to the normal “N” part of the “NS” (or “NIS”) junction, and therefore increase cooling performance.

An embodiment as described hereinabove with a superposition of superconducting materials can be combined with one or the other of those described hereinabove, in particular in relation to FIG. 3 or to FIG. 4.

Thus, an element 51 formed from a superposition of two superconducting materials 47, 49 can itself be surrounded by a dielectric casing 39 as in FIG. 18 and/or be disposed on a dielectric zone 38 formed from a semiconductor oxide as in FIG. 19.

An NIS1S2 configuration as illustrated in FIG. 21 can thus be implemented, where “N” is the normal zone formed by the doped semiconductor portion, “I” is the insulating zone, “S1” is the superconducting material with the highest gap, and “S2” is a superconducting material with a lower gap than the superconducting material “S1”.

The second contact element 52, through which the current I exits, can advantageously be provided with a structure which can be identical to that of the first element 51 and/or including one or the other of the arrangements described hereinabove in relation to FIGS. 2 to 5. Thus, it can be provided to produce an SINIS (Superconductor Insulator Normal Insulator Superconductor) type arrangement with two NIS junctions in series. Such a junction arrangement and symmetrization, preferably when at least the superconducting zones are identical, can make it possible to increase the cooling power further.

A particular exemplary embodiment of sizing of elements of the component C₁ of FIG. 1 is given in the table below, in the particular case where the elements 51, 52 have a configuration such as for example in FIG. 2, 3 or 4 and form a junction:

| | SIZING: | | | | | |
|---|---|---|---|---|---|---|
| | Thickness | | Width | | Length | |
| | (dimension measured | | (dimension measured | | (dimension measured | |
| Layer | parallel to the z axis) | | parallel to the y axis) | | parallel to the x axis) | |
| Track 101 | 10 to 500 | nm | 50 nm to 50 μm | | >100 | nm |
| Element 51, 52 or | 50 to 200 | nm | 30 to 100 | nm | 30 to 100 | nm |
| part 40 of this | | | | | | |
| element 51, 52 | | | | | | |
| Dielectric | 2 to 10 | nm | 30 to 100 | nm | 30 to 100 | nm |
| 38 or 39 | | | | | | |
| Source/drain | 10 to 30 | nm | 40 to 300 | nm | >50 | nm |
| region 13s, 13d | | | | | | |
| Channel 12a | 10 to 20 | nm | 30 to 60 | nm | >100 | nm |
| Gate 22₁ | 20 to 50 | nm | >100 | nm | 20 to 50 | nm |

In the exemplary embodiment described hereinabove in relation to FIG. 1, it is provided to dispose the structure 150 for cooling the component C₁ on its source region 13s.

Alternatively, such a structure 150 can be disposed on the second charge or dopant reservoir, in other words on the drain region 13d of the component C₁.

Such a structure 150 can also be disposed both on the drain region 13d and on the source region 13s.

Thus, in FIG. 6, the structure 150 for cooling the component C₁, provided with the elements 51, 52 in contact on the source region 13s also has other elements 53, 54 in contact on the drain region 13d. The cooling structure 150 thus includes a third contact element 53 and a fourth contact element 54, each in contact with the drain semiconductor region 13d. The third contact element 53 and the fourth contact element 54 are here respectively connected to a third metal track 103 and a fourth metal track 104, to allow the application of suitable polarization potentials and/or signals to them. The third metal track 103 and the fourth metal track 104 can be formed in the same interconnect layer as the tracks 101, 102 and are preferably made of superconducting metal material, for example based on the same superconducting metal material as the tracks 101, 102. The third element 53 and the fourth element 54 can have a similar structure to that of the first element 51 and/or adopting one or other of the configurations described hereinabove in relation to FIGS. 2 to 5, 18, 19. The cooling current capable of being established between the elements 51, 52 and that between the elements 53, 54 are shown with dotted lines.

As an alternative to one or other of the examples described hereinabove, the cooling structure 150 can be provided this time at one or more quantum dot control gates.

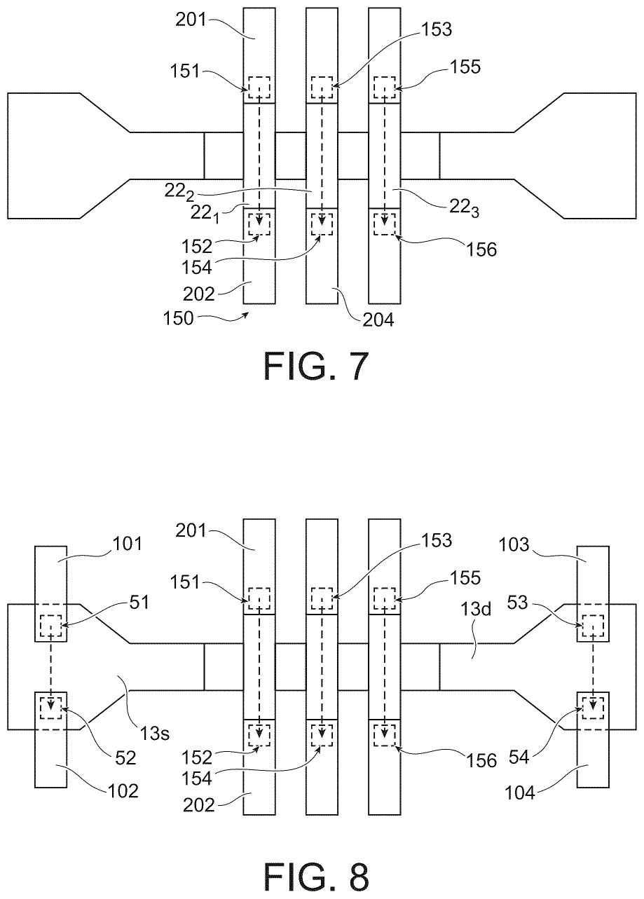

Thus, in the exemplary embodiment illustrated in FIG. 7, a contact element 151 and another contact element 152 are disposed, each in contact with an electrostatic control gate, the contact element(s) 151 each forming with a gate portion 22₁, in particular a preferably doped semiconductor portion with which it/they is/are in contact, a cooling tunnel junction, in particular of the NIS or NS type.

The contact elements 151, 152 can have a similar structure to that of the element 51 described hereinabove and/or a configuration according to any one of the options described hereinabove in relation to FIGS. 2 to 5, 18, 19. The contact elements 151, 152 are here also connected respectively to a metal track 201 and a metal track 202 based on a superconducting material, typically formed in a metal interconnect layer, for example the first layer M1 commonly known as “metal 1”. In the particular embodiment of FIG. 7, each of the control gates can be cooled. Thus, on a second control gate 22₂ the contact elements 153, 154 are also disposed to circulate a current, whereas on a third control gate 22₃ the contact elements 155, 156 are also arranged to circulate a current making it possible to cool this gate 22₃.

Another embodiment provides a cooling structure partly formed on at least one of the source and/or drain regions and partly formed on one or more control gates.

Thus, in another exemplary embodiment illustrated in FIG. 8, the first element 51 and the second element 52 are provided in contact with the source region 13s, the third element 53 and the fourth element 54 in contact with the drain region 13d, and the elements 151, 152, 153, 154, 155, 156 each in contact with a control gate 22₁, 22₂, 22₃. Thus, cooling currents can be circulated respectively through the source region 13s, through the drain region 13d and through each of the gates 22₁, 22₂, 22₃.

In one or other of the examples described hereinabove, a cooling structure is provided for circulating a current in a source region and/or in a drain region and/or in one or more electrostatic control gates of a component C₁ provided to accommodate one or more quantum dots BQ1, BQ2, BQ3.

Such a cooling structure can also be applied to another part of the component C₁ or to another component, dedicated this time to detecting quantum state(s), for example the respective state(s) of the quantum dots BQ1, BQ2, BQ3 of the component C₁.

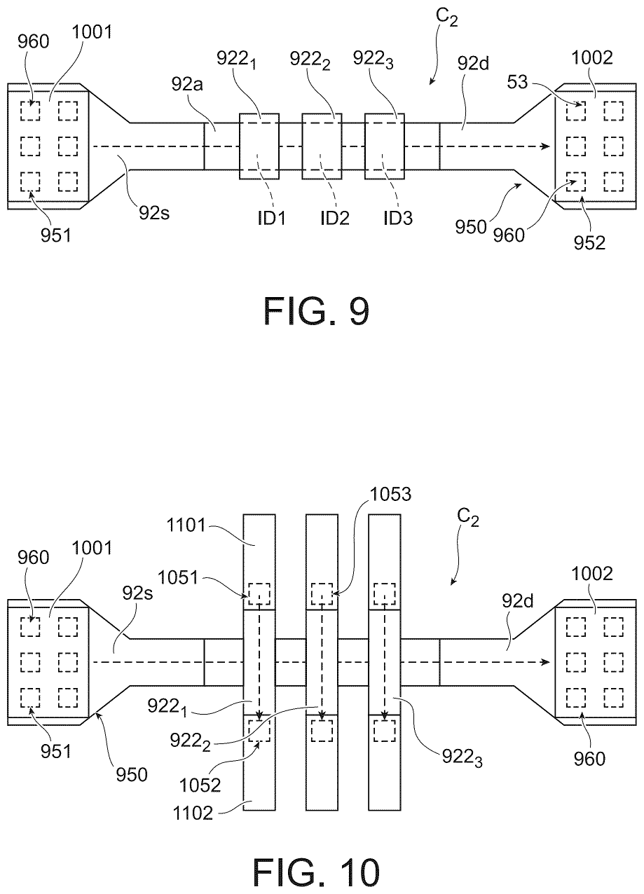

In the exemplary embodiment illustrated in FIG. 9, a cooling structure 950 is provided on another component C₂ including a so-called “channel” semiconductor region 92a, arranged between a source semiconductor region 92s and a drain semiconductor region 92d.

Electrostatic control gates 922₁, 922₂, 922₃ are provided facing semiconductor islands ID1, ID2, ID3 of the channel region 92a, here known as “detection islands” and each provided to detect the quantum state of an associated quantum dot (not shown). The device is here provided with a structure 950 for cooling the component C₂ by circulating a current in the channel region 92a, for example from the source semiconductor region 92s to the drain semiconductor region 92d. The structure 950 thus includes a contact element 951 and a contact element 952, respectively in contact with the source semiconductor region 92s and the drain semiconductor region 92d, the contact elements 951, 952 each forming with semiconductor portions of the source and drain regions at least one cooling tunnel junction, in particular of the NIS or NS type. Insofar as the detection islands ID1, ID2, ID3 of the component C₂ are adapted here to read a quantum state rather than store a quantum state, circulating a current through the channel region 92a in order to cool the component C₂ is not likely to alter quantum information or cause its loss.

According to a particular embodiment, the cooling structure 950 advantageously has elements 951, 952 formed here of several pads 960 placed in parallel and each in contact with a source 92s or drain 92d semiconductor region portion. Each contact pad 960 can have a similar structure to that of a contact element 51 as described hereinabove and/or as illustrated in one of FIGS. 2 to 5, 18, 19.

The contact pads 960 of the contact element 951 are here connected in parallel to the same metal track 1001, preferably made of superconducting metal material. Similarly, the contact pads 960 of the contact element 952 can be connected in parallel to the same metal track 1002, preferably made of superconducting metal material. Such parallelization of the cooling tunnel junctions can make it possible to improve cooling by reducing the total resistance of the R_{T} junction. The metal tracks 1001, 1002 can, once again, be tracks of the same metal interconnect layer, for example of the first metal interconnect layer known as “metal 1”.

Such parallelization of the contacts can also be adapted on the source region 13s and/or on the drain region 13d or even on the control gate(s) of the first component C₁.

Another exemplary embodiment illustrated in FIG. 10 differs from that described hereinabove in that the structure 950 for cooling the component C₂ further provides a contact element 1051 and another contact element 1052, each in contact with an electrostatic control gate 922₁, the contact element(s) 1051, 1052 each forming, with a gate portion, in particular a preferably doped semiconductor portion with which it/they is/are in contact, a cooling tunnel junction, in particular of the NIS or NS type.

The contact elements 1051, 1052 can have a similar structure to that of the element 51 described hereinabove and/or a composition according to one or other of the options described hereinabove in relation to FIGS. 2 to 5, 18, 19.

The contact elements 1051, 1052 are also typically connected respectively to metal tracks 1101, 1102 made of superconducting metal material and produced at the same interconnect layer as the tracks 1001, 1002.

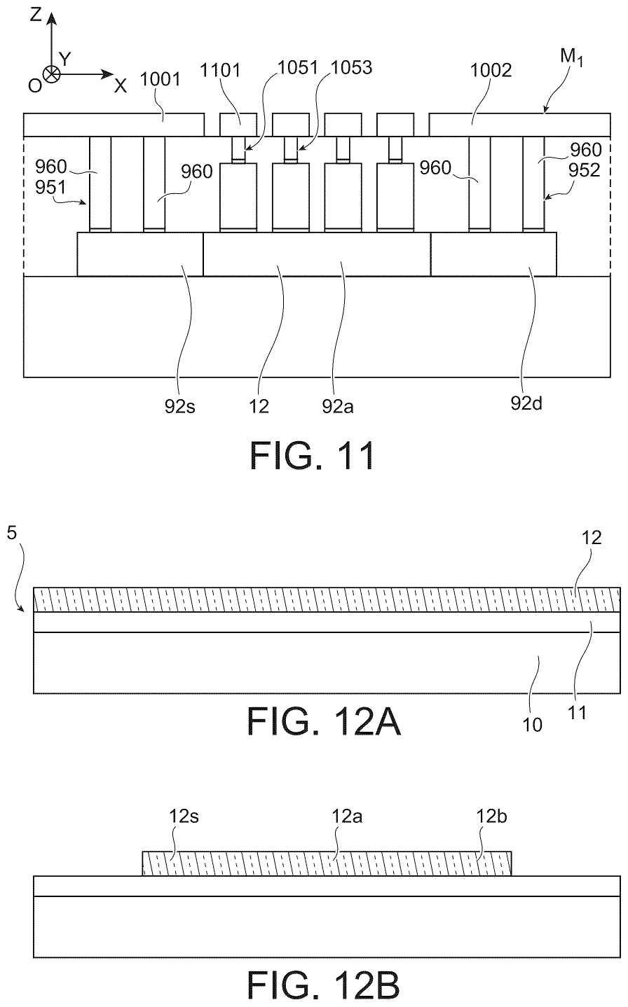

A device having a similar arrangement and this time viewed as a cross-section is illustrated in FIG. 11, with separate gate contact elements 1051, 1053.

In this particular embodiment, the source regions 92s, the channel region 92a and the drain region 92d of the component C₂ are here formed in the same semiconductor layer 12.

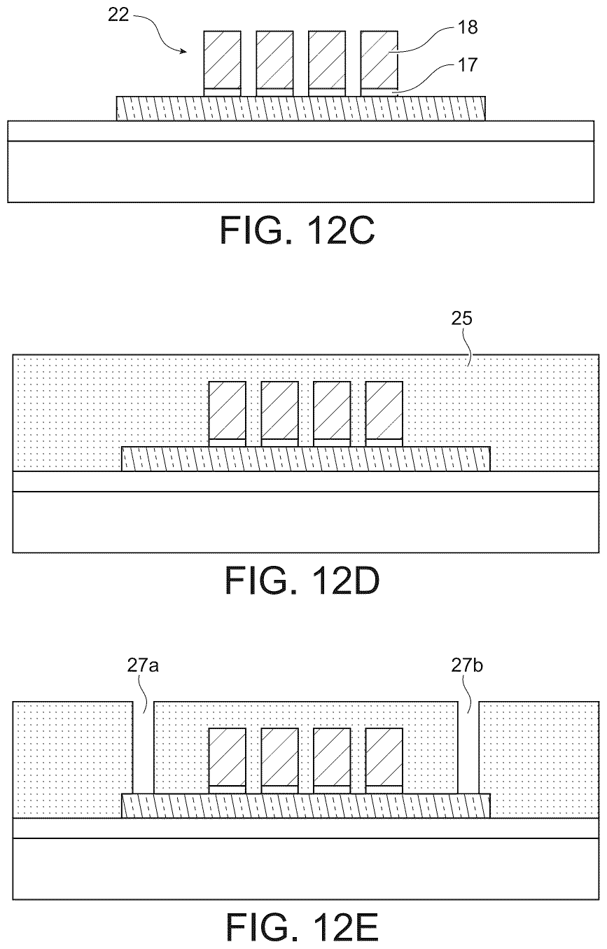

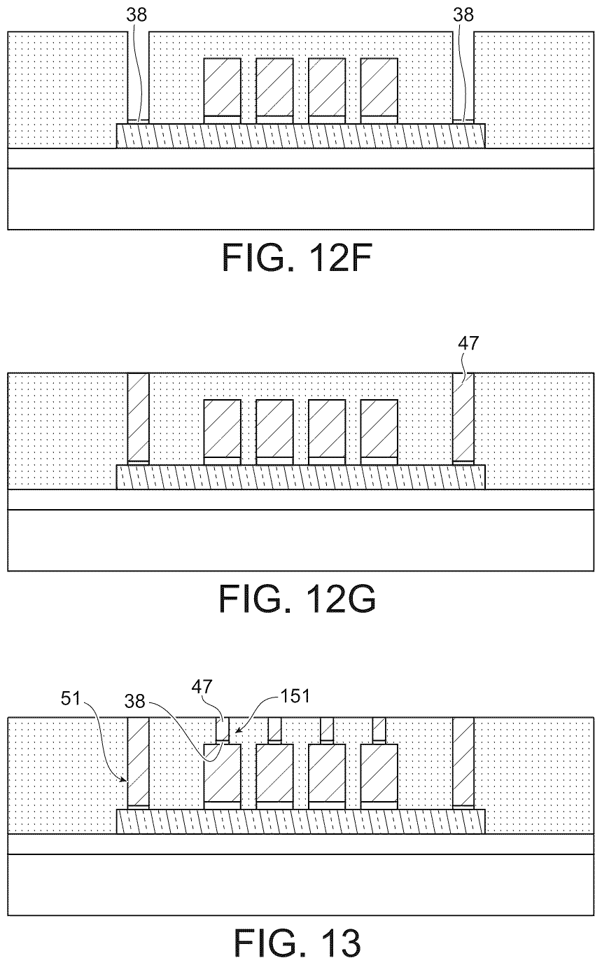

An example of a method for producing a quantum device of a type as described hereinabove will now be given in relation to FIGS. 12A-12F.

A possible starting structure for the embodiment of the device is here in the form of a semiconductor-on-insulator type substrate 5 of which the surface layer 12, of a thickness which can for example be between 5 nm and 25 nm, for example of the order of 12 nm, is here intended to accommodate quantum dots. The semiconductor-on-insulator type substrate 5 can in particular be an SOI (“Silicon On Insulator”) type substrate with a surface layer 12 made of silicon, for example ²⁸Si, in particular when this layer is required to accommodate electron spin qubits. The insulating layer 11 and the support layer 10 of the substrate 5 are typically, respectively, a layer of silicon oxide commonly known as “BOX” (for “Buried Oxide”) and a semiconductor layer, for example based on silicon. The thickness of the insulating layer 11 can for example be between 20 nm and 200 nm, for example of the order of 145 nm.

One or more patterns are then defined in the semiconductor layer 12, of which, as in FIG. 12B, a pattern including a channel region 12a disposed between a semiconductor region 12s intended to form a source region and another semiconductor region 12d intended to form a drain region.

A gate stack covering the semiconductor surface layer 12 is also produced. This gate stack comprises a gate dielectric layer 17, such as for example silicon oxide or a high-k dielectric such as for example Al₂O₃ or HfO₂. The gate dielectric layer can for example be produced with a thickness for example between

2 nm and 20 nm.

The gate dielectric layer 17 is topped with at least one gate material layer 18 which can be formed for example by CVD (“Chemical vapor deposition”) and with a thickness for example between 20 nm and 50 nm. The gate material layer 18 can be formed from at least one semiconductor material such as for example polysilicon or a stack of metal and semiconductor for example of TiN followed by polySi.

One or more gate electrodes are then defined (FIG. 12C) in the gate stack typically by forming a masking wherein patterns are produced, which are then reproduced in the gate stack, for example by anisotropic etching.

Such a step can optionally be followed by the embodiment of insulating spacers (not shown), on either side of the gate electrodes, for example by SiN deposition followed by etching.

Then, again optionally, epitaxial growth of semiconductor material in order to increase the thickness of source and drain regions and form so-called “raised” source and drain regions can be implemented.

Such a step can be accompanied or followed by a step of doping the source and drain regions. Such doping can for example be carried out by implantation and/or in situ during epitaxial growth.

Further insulating spacers can subsequently be produced. In the case where the junctions of the device are siliconized, these additional spacers make it possible to control the position of the siliconization front with respect to the doped regions.

The whole can then be covered with an insulating thickness 25

(FIG. 12D). This insulating thickness 25 can be formed from a CESL (“contact etch stop layer”) type layer, for example made of silicon nitride and a PMD (“pre-metal dielectric”) type layer.

The embodiment of the cooling structure can subsequently be carried out.

To form the contact element(s) of the cooling structure, one or more holes are then made in the insulating thickness 25. Such an embodiment typically comprises photolithography and etching steps. In the particular exemplary embodiment illustrated in FIG. 12E, a hole 27a is produced facing a zone intended to electrically contact a source region as well as a hole 27b facing a zone intended to contact a drain region electrically.

In a particular case as described hereinabove in relation to FIGS. 3 and 4, where it is sought to produce contact elements forming an NIS type cooling junction, a dielectric zone 38 is formed at the bottom of the holes 27a, 27b, for example by oxidation of the semiconductor material located at the bottom of the holes 27a, 27b and/or by deposition of dielectric material. Deposition by PECVD (“Plasma Enhanced Chemical Vapor Deposition”) or PEALD (“Plasma Enhanced Atomic Layer Deposition”) can be implemented in particular.

In the particular example illustrated in FIG. 12F, the dielectric material zone 38 extends only at the bottom of the holes. However, this dielectric zone can, alternatively, in particular in the case of a deposition embodiment, be arranged in a conformal layer coating the bottom as well as the vertical walls of the holes 27a, 27b.

These holes 27a, 27b are then filled using a superconducting metal material 47 (FIG. 12G), for example TiN or TaN or a stack of Ti/TiN or TaN/Ta. Such filling can be performed by CVD and typically followed by a step of CMP (“Chemical mechanical polishing”) planarization in order to remove metal material from the mouth of the holes 27a, 27b.

FIG. 13 illustrates an advantageous case where additional contact elements are provided on the gates 22. The embodiment of these elements can then be similar to that provided above to form contact elements on the source and drain regions. Thus, one or more other holes are made in the insulating thickness 25 respectively facing the gate electrode(s). A dielectric zone 38 is formed at the bottom of these other holes. Then, these other holes are then filled with a superconducting metal material 47. Such filling can be followed by a step of CMP planarization in order to remove the metal material protruding from the mouth of the holes.

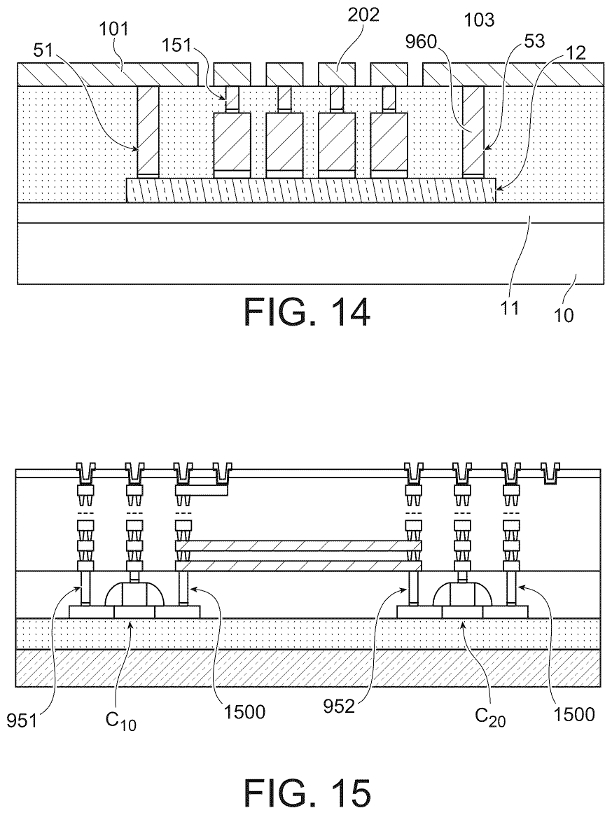

One or more metal tracks 101, 103, 202 can subsequently be formed as in FIG. 14, on the contact element(s) 51, 53, 151 produced, for example by depositing and etching a superconducting metal material which can be chosen from one or more of the following materials: TiN, Nb, NbN, NbTiN, TaN.

A structure 1500 for cooling both components C₁₀ of a semiconductor qubit circuit co-integrated with components C₂₀ of an electronic circuit dedicated to controlling and/or reading the qubits, for example in the form of transistors, in particular cryoCMOS type transistors, is illustrated in FIG. 15 with contact elements 951, 952 forming at least one cooling tunnel junction, in particular of the NIS or NS type and disposed respectively on semiconductor portions of the components C₁₀, C₂₀.

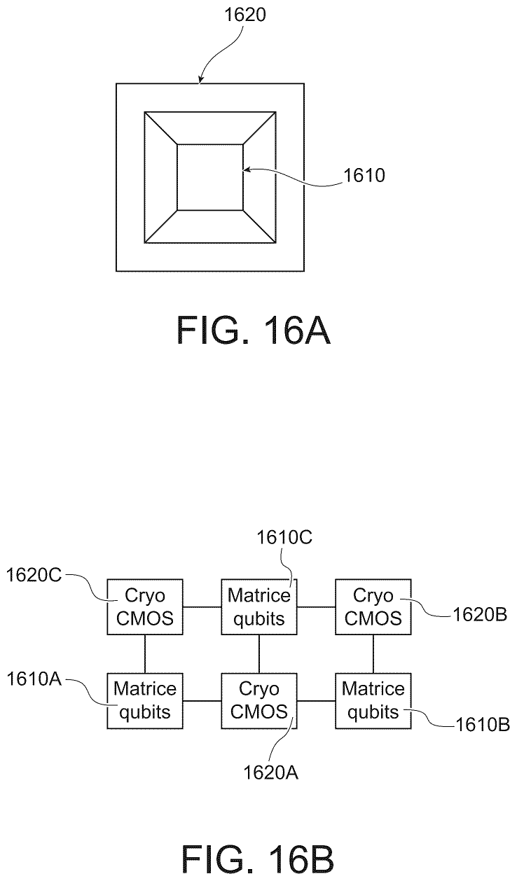

Such a structure 1500 adapts to different types of arrangements of the components C₁₀, C₂₀ and of the circuits to which they belong in particular just as well to an arrangement for example as in FIG. 16A where the control components C₂₀ of a circuit 1620 dedicated to reading and/or controlling the qubits are distributed at the periphery of a quantum component arranged in a qubit matrix circuit 1610, as to a distribution, for example in FIG. 16B with several qubit matrix circuits 1610A, 1610B, 1610C between which circuits 1620A, 1620B, 1620C dedicated to reading and/or controlling the qubits are disposed.

A structure as described previously for cooling a quantum device can be co-integrated with several other means or elements making it possible to promote this cooling or to limit temperature rise.

Thus, for example, one or more structured cavities in a substrate on which the quantum device is produced can be provided. The implementation of such cavities is provided in the patent application filed with the INPI originating from the applicant and having the filing number: FR2310911

Similarly, at least one cavity around metal interconnect layers can be implemented so as to be able to evacuate heat better.

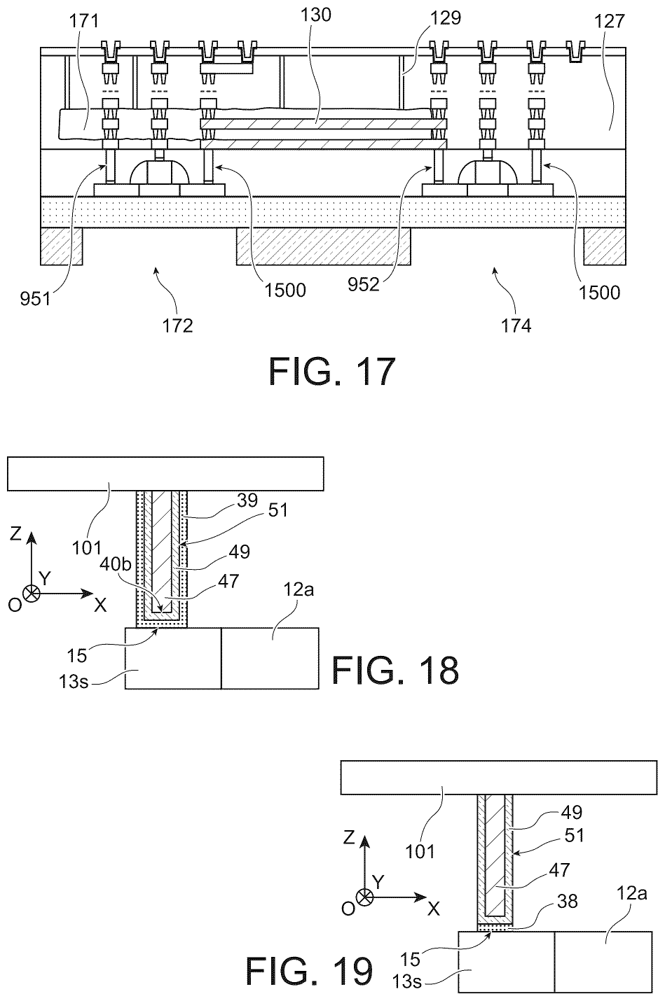

In the exemplary embodiment illustrated in FIG. 17, a cavity 172 produced in the support layer 10 of a substrate facing components C₁₀ of the qubit circuit is provided in particular. Similarly, in the support layer 10 of this substrate, another cavity 174 facing the cryoCMOS type transistor-based control components C₂₀ of the electronic circuit dedicated to controlling and/or reading the qubits is provided. Such cavities 172, 174 typically produced by localized etchings of the substrate make it possible to limit thermal leakage by the latter.

In this exemplary embodiment, another type of cavity 171 is made this time in at least one insulating layer 127 encapsulating one or more metal interconnect lines. Such a cavity 171 can in particular be produced around at least one metal interconnect line 130 between components C₁₀ of the qubit circuit and components C₂₀ of the electronic circuit dedicated to controlling and/or reading the qubits. The cavity 171 forms an empty space or air gap around the metal interconnect line and surrounded by said insulating layer 127. This type of cavity makes it possible to limit thermal leakage by the dielectric present between the interconnect layers. Combined with the use of superconducting material for the metal interconnect line 130, it makes it possible to ensure optimized thermal insulation between the components C₁₀ and C₂₀. It can be implemented in particular by producing openings 129 or trenches 129 through the insulating layer 127 and by performing etching of insulating material exposed by the bottom of these openings or trenches 129.

A cooling structure as described hereinabove can also be integrated into a device as described in applications EP3971983 A1, and EP3971982A1 originating from the applicant and wherein a mixed routing is provided with both routing and/or interconnect lines or tracks made of conductive material and lines or tracks made of superconducting material on different metal interconnect layers of so-called BEOL (“back end of line”) layer(s).

For example, such a mixed routing includes horizontal metal interconnect lines between qubits and cryoCMOS transistors provided in superconducting metal material, whereas vertical connection elements or vias are made of conventional metal material. Such a mixed routing can also comprise, for example, interconnect lines between qubit or cryoCMOS components made of superconducting metal material, on one hand, and interconnect lines to an external reading circuit, on the other, made of conventional metal material such as for example Cu or W.

1. A quantum electronic device, in particular with spin qubits, comprising a substrate and a component disposed on the substrate, the component comprising at least one channel region formed in at least one semiconductor layer and including one or more islands, each island being controlled via an electrostatic control gate and forming a quantum dot or a detection island for reading the quantum state of a quantum dot, the device further comprising: a structure provided to cool said component by circulating a given current between a first contact element with the component and a second contact element with the component, the first contact element comprising at least one given superconducting metal material and being in contact by a first end with a first semiconductor portion of said component so as to form with the first semiconductor portion at least one tunnel junction, in particular of the NS (“Normal” “Superconductor”) or NIS (“Normal” “Insulator” “Superconductor”) type.

2. The device according to claim 1, the first contact element being, from the first end to a second end, formed from said given superconducting metal material.

3. The device according to claim 1, the first contact element including, at the first end, a stack of a dielectric zone in contact with the first semiconductor portion and a section based on said given superconducting metal material.

4. The device of claim 3, wherein the dielectric zone is an oxidized zone of the semiconductor material of the first semiconductor portion.

5. The device according to claim 1, the first contact element including, at the first end, a stack of the given superconducting material and a second superconducting material having a higher gap than the given superconducting material, the second higher-gap superconducting material being in contact with the first semiconductor portion.

6. The device according to claim 1, wherein the given superconducting metal material has a critical temperature T_{C} greater than 4 K.

7. The device according to claim 6, wherein the given superconducting metal is TiN.

8. The device according to claim 1, wherein the channel region extends in a first parallel or substantially parallel direction to a main plane of the substrate and wherein the first element extends in a orthogonal or substantially orthogonal direction to the first direction, the first contact element being connected by a second end to a metal track of superconducting metal material parallel or substantially parallel to the main plane of the substrate.

9. The device according to claim 8, wherein the first contact element is formed from a set of contact pads connected in parallel to the metal track.

10. The device according to claim 1, the second contact element comprising at least one superconducting metal material and being in contact with a second semiconductor portion of said component so as to form with the second semiconductor portion at least one second NS or NIS tunnel junction.

11. The device according to claim 1, the second contact element being in contact with a second semiconductor portion of said component and wherein the channel region extends between source semiconductor region and a drain semiconductor region, the first semiconductor portion and the second semiconductor portion each being portions of said source region or each portions of said drain region.

12. The device according to claim 11, wherein the structure for cooling the component further comprises a third contact element in contact with a third semiconductor portion of the component and a fourth contact element with a fourth semiconductor portion of said component, the third contact element forming a NIS type or NS type tunnel junction with the third semiconductor portion of the component, the third semiconductor portion and the fourth semiconductor portion each being portions of an electrostatic control gate of said component.

13. The device according to claim 1, the second contact element being in contact with a second semiconductor portion of said component wherein the first semiconductor portion and the second semiconductor portion are each portions of an electrostatic control gate.

14. The device according to claim 1, wherein the second contact element is in contact with a second semiconductor portion of said component and wherein the channel region includes one or more detection islands for reading the quantum state of one or more quantum dots of another part of the component or of another component and wherein the channel region extends between a source semiconductor region and a drain semiconductor region, the first portion and the second portion being: respectively a portion of the source region and a portion of the drain region.

15. The device according to claim 1, wherein the substrate comprises a cavity arranged facing said component.

16. The device according to claim 1, wherein each island of the component forms a quantum dot, the device further comprising: another component for reading the quantum state of said component, the device further comprising a structure provided for cooling said other component by circulating a given current between a contact element with said other component and another contact element with said other component, said contact elements forming at least one NIS or NS type tunnel junction with a semiconductor portion of said other component.

16. The device according to claim 15, wherein said component and said other component are connected by a metal interconnect line of a metal interconnect layer arranged in at least one insulating layer, the metal interconnect line being surrounded by a cavity forming an empty space around the metal interconnect line and surrounded by said insulating layer.

17. A method for manufacturing the device according to claim 1, the method comprising steps of:
providing the substrate and the component formed on the substrate,
in at least one insulating layer covering the component, producing at least a first hole and at least a second hole respectively revealing the first semiconductor portion and the second semiconductor portion of said component,
forming the first contact element in the first hole and the second contact element in the second hole, by depositing at least the given superconducting metal material in the first hole and in the second hole.
